(19) United States
(12) Patent Application Publication
(10) Pub. No.: US 2016/0045937 A1
(43) Pub. Date: Feb. 18, 2016

(54) SUBSTRATE CLEANING APPARATUS AND METHOD FOR CLEANING A SUBSTRATE

(71) Applicant: UNITED MICROELECTRONICS CORPORATION, Hsinchu (TW)

(72) Inventors: CHI-PIAO CHENG, New Taipei City (TW); WEN-PEN HO, Tainan (TW); KUAN-TING WU, Citong Township (TW); CHIN-YI CHIU, Tainan (TW)

(73) Assignee: UNITED MICROELECTRONICS CORPORATION, Hsinchu (TW)

(21) Appl. No.: 14/458,211

(22) Filed: Aug. 12, 2014

(51) Int. Cl. B08B 1/04; B08B 1/00; H01L 21/67

(52) U.S. Cl. CPC B08B 1/04; H01L 21/67092; B08B 1/002

(57) ABSTRACT

A substrate cleaning apparatus includes a holder, a brush, a moving element, a driving element and a pressure sensor. The holder is used for disposing a substrate thereon. The moving element is connected to the brush. The driving element is connected to the moving element for proving a lateral pushing power to the moving element such that the moving element and the brush jointly move. The pressure sensor is disposed close to the moving element for sensing the lateral pushing power when the moving element moves to contact with the pressure sensor along a lateral direction, in which the brush moves to laterally push the substrate after the lateral pushing power is sensed to reach a first threshold value by the pressure sensor such that the brush is abutted on the substrate when the brush cleans the substrate.

### FIELD OF THE INVENTION

The invention relates to a cleaning apparatus and a cleaning method, and more particularly to a substrate cleaning apparatus and a method for cleaning a substrate.

### BACKGROUND OF THE INVENTION

In the processes about producing a semiconductor device, it is important to contain a surface clearness of a semiconductor wafer to avoid contamination of a periphery of the semiconductor wafer influencing the treatment quality of the semiconductor wafer.

For example, when some contaminants are stained with the peripheries of the semiconductor wafers to cause the contaminants adhering on the surfaces of the semiconductor wafers, the surfaces of the semiconductor wafers may be contaminated to decrease the treatment qualities of the semiconductor wafers and other types of substrates.

In order to clean a periphery of a substrate such as the semiconductor wafer, a prior-art apparatus for cleaning the periphery of the substrate is provided. The prior-art apparatus includes a turntable which holds and rotates the substrate, and a cylindrical brush for cleaning the peripheral surface of the substrate. In the cleaning process, the brush is moved to touch on the peripheral surface of the substrate held on the turntable, and then the turntable rotates with the substrate held thereon such that a circumferential surface of the brush is kept in abutment against the periphery of the substrate, thereby resulting in the periphery of the substrate being cleaned by the brush.

However, the brush may be offset from a normal position such that the brush will be brought out of abutment against the periphery of the substrate because the prior-art apparatus does not necessarily ensure that the brush is kept in abutment against the periphery of the substrate during the cleaning process. Furthermore, the substrate may be broken when the brush abuts against the peripheral surface of the substrate with over-large pushing power.

### SUMMARY OF THE INVENTION

The invention provides a substrate cleaning apparatus and a method for cleaning a substrate to be capable of avoiding the foregoing disadvantages.

According to an embodiment of the invention, a substrate cleaning apparatus includes a holder, a brush, a moving element, a driving element and a pressure sensor. The holder is used for disposing a substrate thereon. The moving element is connected to the brush. The driving element is connected to the moving element for proving a lateral pushing power to the moving element such that the moving element and the brush jointly move. The pressure sensor is disposed close to the moving element for sensing the lateral pushing power when the moving element moves to contact with the pressure sensor along a lateral direction, in which the brush moves to laterally push the substrate after the lateral pushing power is sensed to reach a first threshold value by the pressure sensor such that the brush is abutted on the substrate when the brush cleans the substrate.

According to another embodiment disclosed herein, a top surface of the brush is connected on a bottom surface of the moving element.

According to another embodiment disclosed herein, the substrate cleaning apparatus further includes a rotating element engaged with the moving element to be jointly connected to the brush for driving the brush to rotate.

According to another embodiment disclosed herein, the moving element and the brush jointly move along the lateral direction.

According to another embodiment disclosed herein, the brush is abutted on a lateral wall of the substrate when the brush contacts with the substrate.

According to another embodiment disclosed herein, the lateral wall of the substrate is vertical to the lateral direction.

According to another embodiment disclosed herein, the driving element is an air cylinder for providing an air pressure to form the lateral pushing power.

According to another embodiment disclosed herein, the holder is rotatable and a rotating direction of the holder is opposite to a rotating direction of the brush.

According to another embodiment disclosed herein, the moving element includes a guide for smoothly moving along the laterally direction.

According to another embodiment of the invention, a method for cleaning a substrate includes several steps as follows. The substrate is disposed on a holder. A lateral pushing power is provided to a moving element such that the moving element and a brush jointly move. The lateral pushing power is sensed when the moving element moves to contact with the pressure sensor along a lateral direction. The brush is driven to move such that the brush is laterally abutted on the substrate after the lateral pushing power is sensed to reach a first threshold value. The substrate is cleaned when the brush is abutted on the substrate.

According to another embodiment disclosed herein, a top surface of the brush is connected on a bottom surface of the moving element.

According to another embodiment disclosed herein, a rotating element engaged with the moving element is provided to be connected to the brush for driving the brush to rotate.

According to another embodiment disclosed herein, the moving element and the brush jointly move along the lateral direction.

According to another embodiment disclosed herein, the brush is abutted on a lateral wall of the substrate when the brush contacts with the substrate.

According to another embodiment disclosed herein, the lateral wall of the substrate is vertical to the lateral direction.

According to another embodiment disclosed herein, the lateral pushing power is formed by an air pressure.

According to another embodiment disclosed herein, the holder is rotatable and a rotating direction of the holder is opposite to a rotating direction of the brush.

In the embodiment, the pressure sensor is capable of sensing the pushing power provided by the driving element until the driving element provides a suitable lateral pushing power, in which the suitable lateral pushing power means that the lateral pushing power reaching the first threshold value to drive the moving element, and thus the moving element and the brush are capable of jointly moving toward the substrate, thereby resulting in the brush being abutted to the peripheral surface of the substrate with the suitable lateral pushing power. Therefore, the brush is stably capable of being kept in abutment against the peripheral surface of the substrate so that the substrate may have a highly cleaning efficiency and contain an optimum treatment quality during the cleaning process.

### BRIEF DESCRIPTION OF THE DRAWINGS

The invention will become more readily apparent to those ordinarily skilled in the art after reviewing the following detailed description and accompanying drawings, in which:

FIG. 1 illustrates a lateral view of a substrate cleaning apparatus according to an embodiment of the invention; and

FIGS. 2A˜2C are flow diagrams illustrating a method for cleaning a substrate according to an embodiment of the invention.

### DETAILED DESCRIPTION OF PREFERRED EMBODIMENTS

The invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

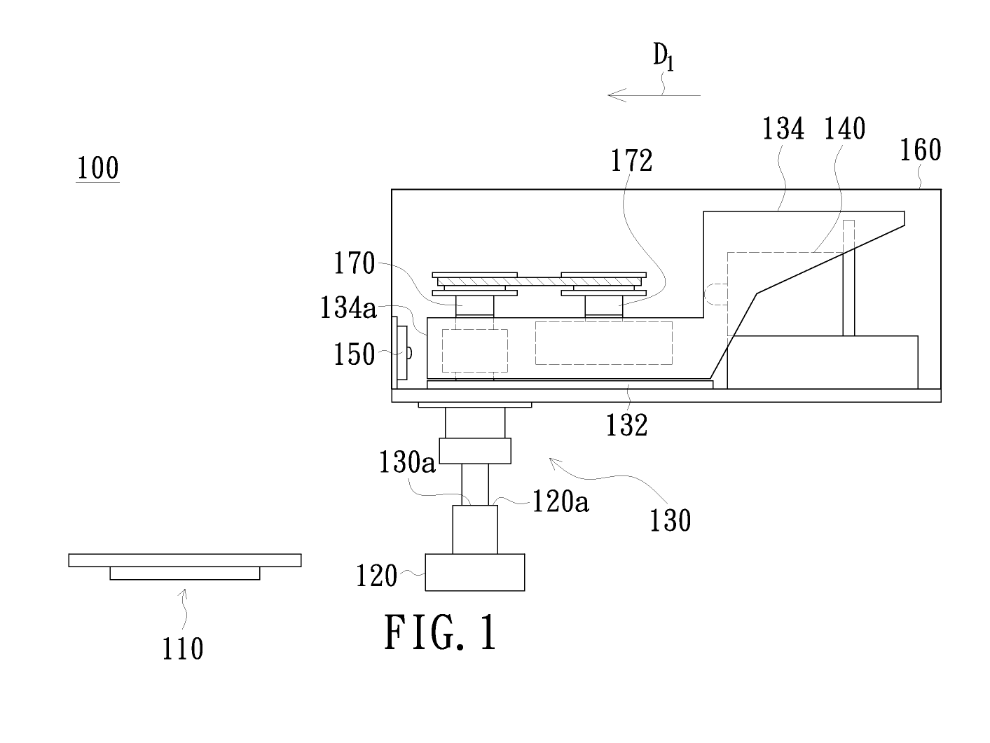

FIG. 1 shows a lateral view of a substrate cleaning apparatus according to an embodiment of the invention. As shown in FIG. 1, the substrate cleaning apparatus 100 is used for cleaning a periphery of a substrate (not shown), in which the substrate cleaning apparatus 100 includes a holder 110, a brush 120, a moving element 130, a driving element 140 and a pressure sensor 150. In this embodiment, the substrate cleaning apparatus 100 may, but be not limited to, include a cover 160 for containing parts of the moving element 130, the driving element 140 and the pressure sensor 150. That is to say, the moving element 130 is penetrated through the cover 160. In addition, the holder 110 is used for disposing the substrate thereon. Furthermore, the holder 110 may be, but not limited to, used to horizontally hold and rotate the substrate.

On the other hand, the brush 120 is used to clean the periphery of the substrate. The moving element 130 is connected to the brush 120. In this embodiment, a top surface 120a of the brush 120 is, but not limited to, connected on a bottom surface 130a of the moving element 130. In addition, the moving element 130 carries the brush 120 to jointly move when the moving element 130 moves along a guide 132.

Moreover, the substrate cleaning apparatus 100 may, but be not limited to, include a rotating element 170 and the rotating element 170 is engaged with the moving element 130 to be jointly connected to the brush 120 for driving the brush 120 to rotate such that the brush 120 may rotate to clean the peripheral surface of the substrate.

The driving element 140 is connected to the moving element 130 for proving a lateral pushing power to drive the moving element 130 such that the moving element 130 moves by the lateral pushing power, thereby resulting in the moving element 130 carrying the brush 120 to jointly move. For example, the driving element 140 may be, but not limited to, an air cylinder providing an air pressure to be the lateral pushing power. That is to say, the lateral pushing power is formed by an air pressure.

The pressure sensor 150 is disposed adjacent to the moving element 130 for sensing the lateral pushing power. For example, when the driving element 140 pushes a shell 134 of the moving element 130 with the lateral pushing power, the moving element 130 may move by the lateral pushing power such that a terminal 134a of the shell 134 of the moving element 130 is abutted on the pressure sensor 150 thereby resulting in the pressure sensor 150 being capable of sensing the lateral pushing power. The pressure sensor 150 can sense the lateral pushing power to reach a first threshold value, in which the pressure sensor 150 can sense the lateral pushing power to reach a suitable lateral pushing power. In other words, when the lateral pushing power reaches the first threshold value, the brush 120 can be abutted on the substrate by the suitable lateral pushing power such that the substrate may be cleaned.

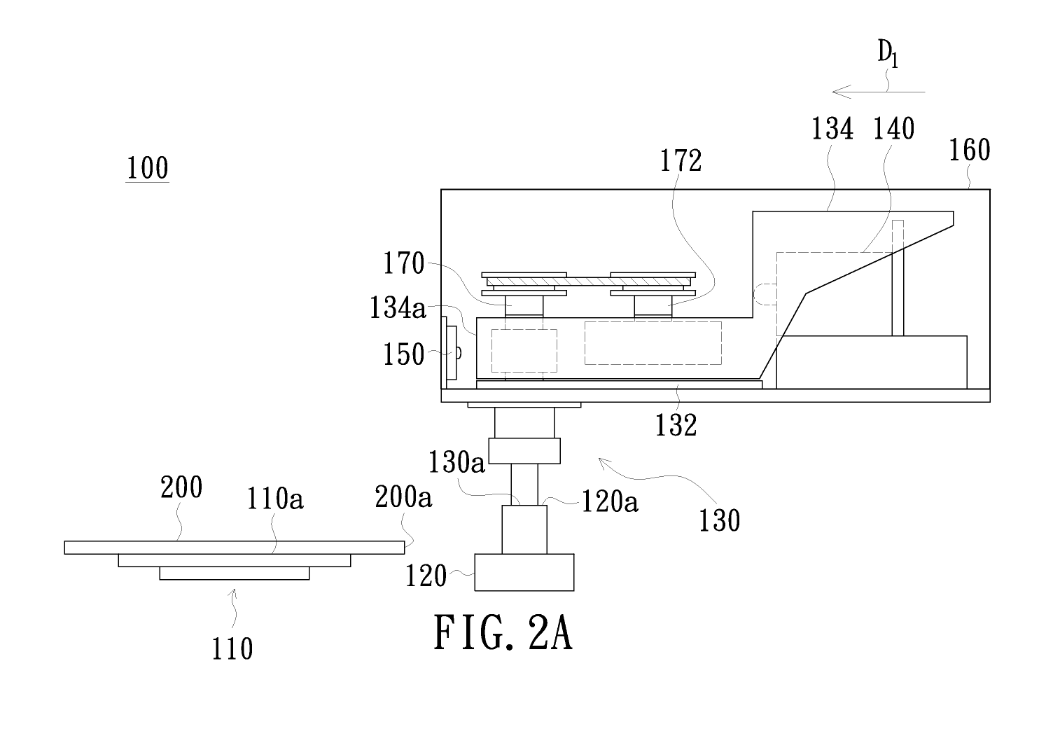

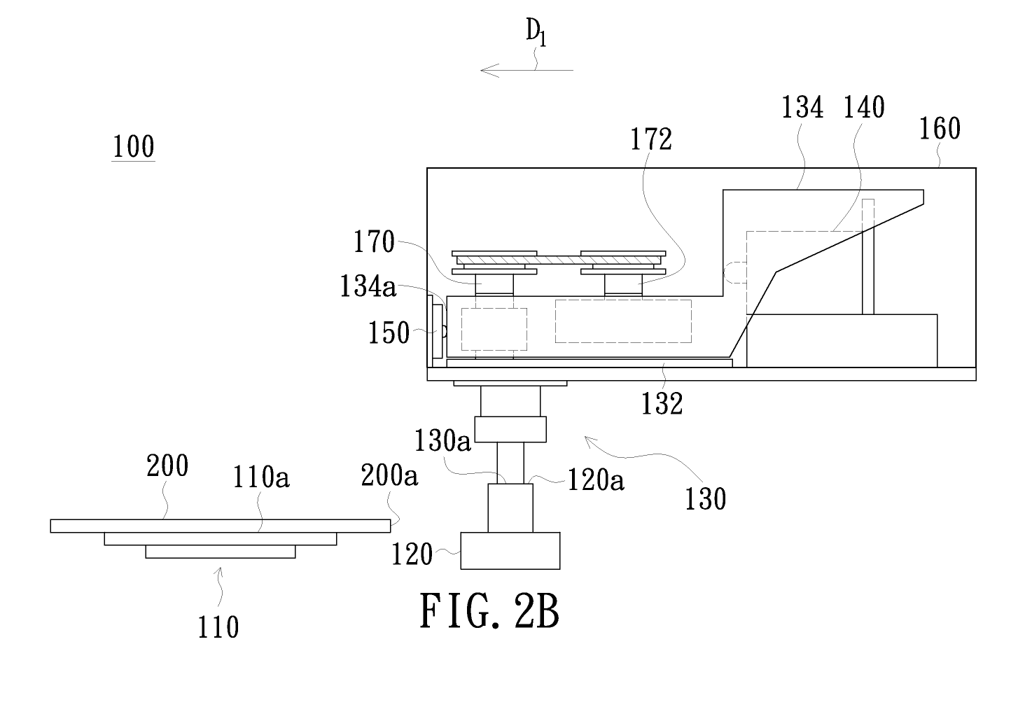

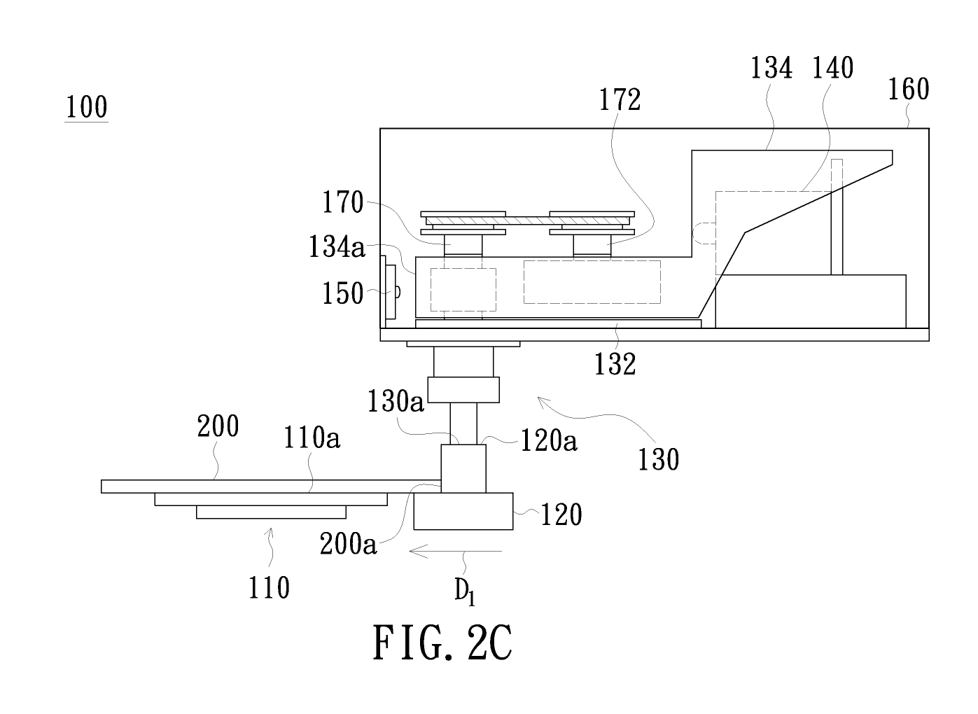

FIGS. 2A˜2C are flow diagrams illustrating a method for cleaning a substrate according to an embodiment of the invention. It should be understood that the method for cleaning the substrate is, but not limited to, applied to the substrate cleaning apparatus 100 of the embodiment of FIG. 1.

As shown in FIG. 2A, a substrate 200 is disposed on a top surface 110a of the holder 100, that is to say that the holder 100 horizontally holds the substrate 200. Then, a lateral pushing power is provided to drive the moving element 130 to move by the driving element 140 such that the moving element 130 and the brush 120 could jointly move. For example, the driving element 140 may be an air cylinder to provide an air pressure and the air pressure forms the lateral pushing power to push the shell 134 of the moving element 130 such that the moving element 130 carries the brush 120 to jointly move along a lateral direction D1. In this embodiment, the substrate 200 may be, but not limited to, a single semiconductor wafer.

As shown in FIG. 2B, when the moving element 130 carries the brush 120 to jointly move along the lateral direction D1 and the terminal 134a of the shell 134 of the moving element 130 contacts with the pressure sensor 150 along the lateral direction D1, the lateral pushing power is sensed by the pressure sensor 150. When the lateral pushing power provided by the driving element 140 is sensed to reach a first threshold value by the pressure sensor 150, the moving element 130 may carry the brush 120 to move to be abutted on the substrate 200 such that the brush 120 is abutted on the substrate with a suitable lateral pushing power. It should be understood that the suitable lateral pushing power means the lateral pushing power reaching the first threshold value such that the brush 120 may be stably abutted on the substrate 200 and the undesired crack of the substrate 200 owing to receiving over-large pushing power can be avoided.

As shown in FIG. 2C, after the lateral pushing power is sensed to reach the first threshold value by the pressure sensor 150, the brush 120 is carried by the moving element 130 to move until the brush 120 is laterally abutted on the substrate 200 with the lateral pushing power reaching the first threshold value such that the brush 120 may be stably abutted on the substrate 200 and the undesired crack of the substrate 200 owing to receiving over-large pushing power can be avoided. In this embodiment, the substrate 200 is cleaned when the brush 120 is abutted on the substrate 200, in which the brush 120 is, but not limited to, abutted on a lateral wall 200a of the substrate 200 when the brush 120 contacts with the substrate 200 and the lateral wall 200a of the substrate 200 is, but not limited to, vertical to the lateral direction D1. Moreover, the holder 110 is rotatable such that the brush 120 and the substrate 200 are capable of rotating with each other, thereby resulting in the substrate 200 having a highly cleaning efficiency during the cleaning process and containing an optimum treatment quality, in which a rotating direction of the holder 110 may, but be not limited to, be opposite to a rotating direction of the brush 120 driven by the rotating element 170.

According to the embodiments described above, the pressure sensor is capable of sensing the pushing power provided by the driving element until the driving element provides a suitable lateral pushing power, in which the suitable lateral pushing power means that the lateral pushing power reaching the first threshold value to drive the moving element, and thus the moving element and the brush are capable of jointly moving toward the substrate with the suitable lateral pushing power, thereby resulting in the brush being abutted to the peripheral surface of the substrate with the suitable lateral pushing power. Therefore, the brush is stably capable of being kept in abutment against the peripheral surface of the substrate so that the substrate may have a highly cleaning efficiency and contain an optimum treatment quality during the cleaning process. In addition, the lateral pushing power can be controlled by an online fault detection and classification (FDC) system.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A substrate cleaning apparatus comprising:
a holder for disposing a substrate thereon;
a brush;
a moving element connected to the brush;
a driving element connected to the moving element for proving a lateral pushing power to the moving element such that the moving element and the brush jointly move; and
a pressure sensor disposed close to the moving element for sensing the lateral pushing power when the moving element moves to contact with the pressure sensor along a lateral direction wherein the brush moves to laterally push the substrate after the lateral pushing power is sensed to reach a first threshold value by the pressure sensor such that the brush is abutted on the substrate when the brush cleans the substrate.

2. The substrate cleaning apparatus according to claim 1, wherein a top surface of the brush is connected on a bottom surface of the moving element.

3. The substrate cleaning apparatus according to claim 1, further comprising a rotating element engaged with the moving element to be jointly connected to the brush for driving the brush to rotate.

4. The substrate cleaning apparatus according to claim 1, wherein the moving element and the brush jointly move along the lateral direction.

5. The substrate cleaning apparatus according to claim 1, wherein the brush is abutted on a lateral wall of the substrate when the brush contacts with the substrate.

6. The substrate cleaning apparatus according to claim 5, wherein the lateral wall of the substrate is vertical to the lateral direction.

7. The substrate cleaning apparatus according to claim 1, wherein the driving element is an air cylinder for providing an air pressure to form the lateral pushing power.

8. The substrate cleaning apparatus according to claim 1, wherein the holder is rotatable and a rotating direction of the holder is opposite to a rotating direction of the brush.

9. The substrate cleaning apparatus according to claim 1, wherein the moving element comprises a guide for moving along the laterally direction.

10. A method for cleaning a substrate, comprising:
disposing the substrate on a holder;
providing a lateral pushing power to a moving element such that the moving element and a brush jointly move;
sensing the lateral pushing power when the moving element moves to contact with the pressure sensor along a lateral direction;
driving the brush to move such that the brush is laterally abutted on the substrate after the lateral pushing power is sensed to reach a first threshold value; and
cleaning the substrate when the brush is abutted on the substrate.

11. The method according to claim 10, wherein a top surface of the brush is connected on a bottom surface of the moving element.

12. The method according to claim 10, further comprising:
providing a rotating element engaged with the moving element to be connected to the brush for driving the brush to rotate.

13. The method according to claim 10, wherein the moving element and the brush jointly move along the lateral direction.

14. The method according to claim 10, wherein the brush is abutted on a lateral wall of the substrate when the brush contacts with the substrate.

15. The method according to claim 14, wherein the lateral wall of the substrate is vertical to the lateral direction.

16. The method according to claim 10, wherein the lateral pushing power is formed by an air pressure.

17. The method according to claim 10, wherein the holder is rotatable and a rotating direction of the holder is opposite to a rotating direction of the brush.
